(19) United States
(12) Patent Application Publication
(10) Pub. No.: US 2011/0299259 A1
(43) Pub. Date: Dec. 8, 2011

(54) CIRCUIT BOARD WITH CONDUCTOR POST STRUCTURE

(76) Inventors: Yu-Ling Hsieh, Xindian City (TW); I-Tseng Lee, Kaohsiung City (TW); Yi-Hsiu Liu, Renwu Township (TW); Jen-Yi Tsai, Taichung City (TW); Cheng-hua Fan, Kaohsiung City (TW)

(21) Appl. No.: 12/794,535

(22) Filed: Jun. 4, 2010

(51) Int. Cl. H01R 9/00; H05K 1/11; B23K 1/20

(52) U.S. Cl. 361/774; 228/203; 174/267

(57) ABSTRACT

Various circuit board interconnect conductor structures and methods of making the same are disclosed. In one aspect, a method of manufacturing is disclosed that includes forming a conductor post on a side of a circuit board. The conductor post includes an end projecting away from the side of the circuit board. A solder mask is applied to the side of the circuit board to cover the conductor post. A thickness of the solder mask is reduced so that a portion of the conductor post projects beyond the solder mask.

### BACKGROUND OF THE INVENTION

1. Field of the Invention

This invention relates generally to semiconductor processing, and more particularly to circuit board interconnect structures and methods of making the same.

2. Description of the Related Art

Many present day semiconductor chips are mounted to a package substrate that is, in-turn, mounted to another printed circuit board. A package substrate is typically larger in size than its companion chip. A package substrate serves several purposes. In one aspect, a package substrate provides a convenient interface between a typically small semiconductor chip and a normally much larger printed circuit board. In another aspect, a package substrate provides a mounting surface and conductive pathways for a variety of passive components, such as capacitors, that are useful for the operation of but cannot be easily incorporated into a semiconductor chip.

In order to serve as an interface between a semiconductor chip and a printed circuit board, a typical package substrate includes a collection of conductor lines that may be interspersed in several different layers of insulating material. A variety of schemes are used to link the substrate conductor lines to a printed circuit board. Pins, solder balls and land pads are examples of structures used to connect to a printed circuit board. Similarly, a variety of techniques are used to electrically connect a semiconductor chip to the conductor lines of a package substrate. Two such techniques are bond line connections and flip-chip solder bump connections.

In one conventional flip-chip solder bump design, a package substrate includes a mounting surface that is destined to receive a semiconductor chip. The mounting surface includes a collection of conductive bump pads and component pads. A solder mask is formed on the mounting surface and patterned lithographically with a series of openings that lead to the bump pads and the component pads. The openings leading to the bumps pads are patterned with a lateral dimension that is smaller than the lateral dimension of the bump pad. A solder stencil is next placed on the solder mask. The solder stencil has an array of openings that line up vertically with the collection of openings in the solder mask. Solder paste is pressed into the openings and the stencil is removed. To provide the solder structures present in the bump pad openings with an improved and consistent shape, a coining operation is performed. The coined solder structures are often referred to as “pre-solders”. Conventional pre-solders are typically composed of low temperature melting point solders, such as tin-lead eutectics.

Coining increases the footprint of the pre-solder and thus imposes a limit to minimum bump pitch. In addition, the usage of solder paste spread out over thousands or millions of packages represents a significant material cost. Another conventional design described in detail below utilizes a plated conductor structure instead of a pure solder joint. However the conventional conductor structure includes a top flange that, like a coined pre-solder, limits interconnect pitch.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes forming a conductor post on a side of a circuit board. The conductor post includes an end projecting away from the side of the circuit board. A solder mask is applied to the side of the circuit board to cover the conductor post. A thickness of the solder mask is reduced so that a portion of the conductor post projects beyond the solder mask.

In accordance with another aspect of an embodiment of the present invention, a method of manufacturing is provided that includes forming plural conductor posts on a side of a semiconductor chip package substrate. Each of the conductor posts includes an end projecting away from the side of the circuit board. A solder mask is applied to the side of the semiconductor chip package substrate to cover the plural conductor posts. A thickness of the solder mask is reduced so that a portion of each of the conductor posts projects beyond the solder mask.

In accordance with another aspect of an embodiment of the present invention, an apparatus is provided that includes a circuit board including a side. A solder mask is coupled to the side of the circuit board. A conductor post is coupled to the side of the circuit board and includes a first end projecting into the solder mask and a second end projecting out of the solder mask. The second end is not wider than the first end.

### BRIEF DESCRIPTION OF THE DRAWINGS

The foregoing and other advantages of the invention will become apparent upon reading the following detailed description and upon reference to the drawings in which:

FIG. 1 is an exploded pictorial view of an exemplary embodiment of a semiconductor chip device that includes a semiconductor chip flip-chip mounted to a circuit board;

FIG. 2 is a plan view of the circuit board of FIG. 1;

FIG. 3 is a sectional view of FIG. 2 taken at section 3-3;

FIG. 4 is a sectional view like FIG. 3, but depicting exemplary fabrication of a conductive seed layer on the circuit board;

FIG. 5 is a sectional view like FIG. 4, but depicting patterning of a mask on the circuit board;

FIG. 6 is a sectional view like FIG. 5, but depicting conductor pad fabrication and application of another mask;

FIG. 7 is a sectional view like FIG. 6, but depicting formation of an exemplary conductor post on the circuit board;

FIG. 8 is a sectional view like FIG. 7, but depicting mask removal;

FIG. 9 is a sectional view like FIG. 8, but depicting application of a solder mask to the circuit board;

FIG. 10 is a sectional view like FIG. 9, but depicting the thinning of the solder mask;

FIG. 11 is a sectional view like FIG. 10, but depicting application of a conductor cap to the conductor post;

FIG. 12 is a sectional view like FIG. 11, but depicting application of an alternate exemplary conductor cap to a conductor post;

FIGS. 13-19 depict successive sectional views of a conventional semiconductor chip package substrate undergoing processing to establish a conventional conductor structure with a base portion and flange portion projecting across a solder mask; and

FIG. 19 is a plan view of a portion of the conventional solder mask depicting three conventional flanged conductor structures.

### DETAILED DESCRIPTION OF SPECIFIC EMBODIMENTS

Various circuit board interconnect conductor structures and methods of making the same are disclosed. In one aspect, a method of manufacturing is disclosed that includes forming a conductor post on a side of a circuit board. The conductor post includes an end projecting away from the side of the circuit board. A solder mask is applied to the side of the circuit board to cover the conductor post. A thickness of the solder mask is reduced so that a portion of the conductor post projects beyond the solder mask. After solder mask thinning, the conductor post projects beyond the solder mask but without a flange. Finer pitches for conductor posts may be achieved. Additional details will now be described.

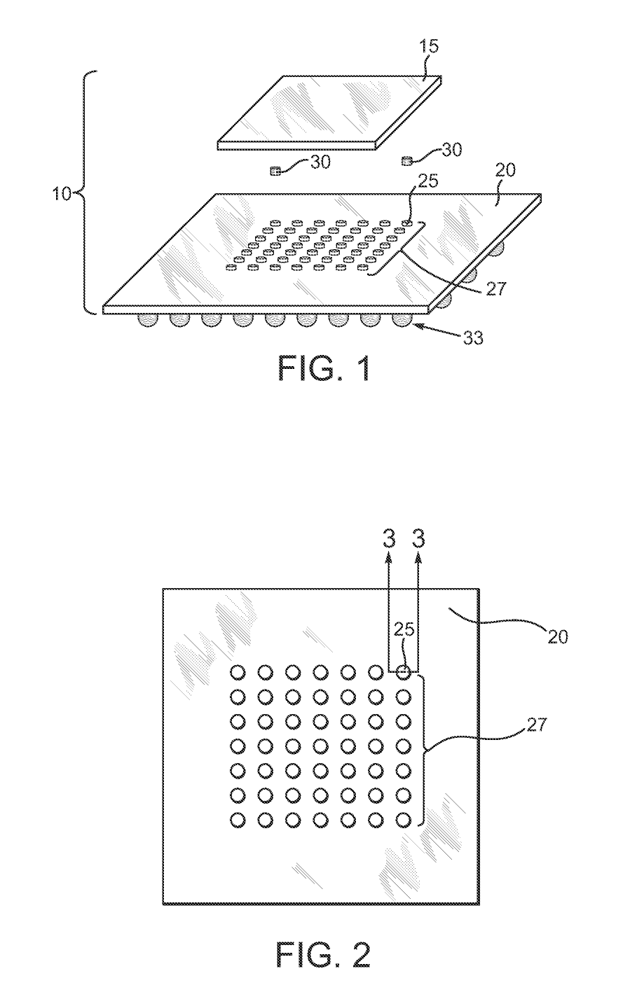

In the drawings described below, reference numerals are generally repeated where identical elements appear in more than one figure. Turning now to the drawings, and in particular to FIG. 1 therein is depicted an exploded pictorial view of an exemplary embodiment of a semiconductor chip device 10 that includes a semiconductor chip 15 flip-chip mounted to a circuit board 20. The circuit board 20 includes plural conductor structures 25 arranged in an array 27 that are designed to electrically interface with corresponding conductor structures (not shown) of the semiconductor chip 15 by way of conductor structures, two of which are shown and labeled 30. The array 27 is depicted with only a few tens of conductor structures 25 for simplicity of illustration. However, the skilled artisan will appreciate that the conductor structures 25 may number into the hundreds or thousands depending upon the complexities of the circuit board 20 and the semiconductor chip 15. Furthermore, the array 27 may be symmetric as shown or asymmetric as desired. Additional details of the conductor structures 25 will be described in conjunction with subsequent figures. The conductor structures 30 may be solder joints, conductive pillars, combinations of the two or other types of interconnect structures as desired. A ball grid array 33 may be fitted to the circuit board 20 to provide for interconnection with another circuit board or device (not shown). Of course, many other interconnect schemes may be used, such as pin grid arrays, land grid arrays or others.

The semiconductor chip 15 may be any of a myriad of different types of circuit devices used in electronics, such as, for example, microprocessors, graphics processors, combined microprocessor/graphics processors, application specific integrated circuits, memory devices or the like, and may be single or multi-core. Multiple planar and/or stacked dice may be used. The semiconductor chip 15 may be fabricated using silicon, germanium or other semiconductor materials. If desired, the semiconductor chip 15 may be fabricated as a semiconductor-on-insulator substrate or as bulk semiconductor.

The circuit board 20 may be configured as a semiconductor chip package substrate, a circuit card, a motherboard or virtually any type of circuit board. Various materials may be used, such as ceramics or organic materials as desired. If organic, the circuit board 20 may be monolithic or consist of multiple layers of metallization and dielectric materials. The circuit board 20 may interconnect electrically with external devices, such as a socket, in a variety of ways, such as the depicted pin grid array 30, or optionally a land grid array, a ball grid array or other configuration. The number of individual layers for the circuit board 20 is largely a matter of design discretion. In certain exemplary embodiments, the number of layers may vary from two to sixteen. If such a build-up design is selected, a standard core, thin core or coreless arrangement may be used. The dielectric materials may be, for example, epoxy resin with or without fiberglass fill. The circuit board 20 may be provided with one or more passive devices (not shown), which may be capacitors, resistors, inductors or other components.

FIG. 2 is a plan view of the circuit board 20. Note that section 3-3 passes through the conductor structure 25 and a small portion of the circuit board 20. The succeeding sectional views of the conductor structure 25 of the array 27 and the corresponding small portion of the circuit board 20 will be used to describe additional details of the conductor structure 25 that will be exemplary of the other conductor structures of the conductor array 27.

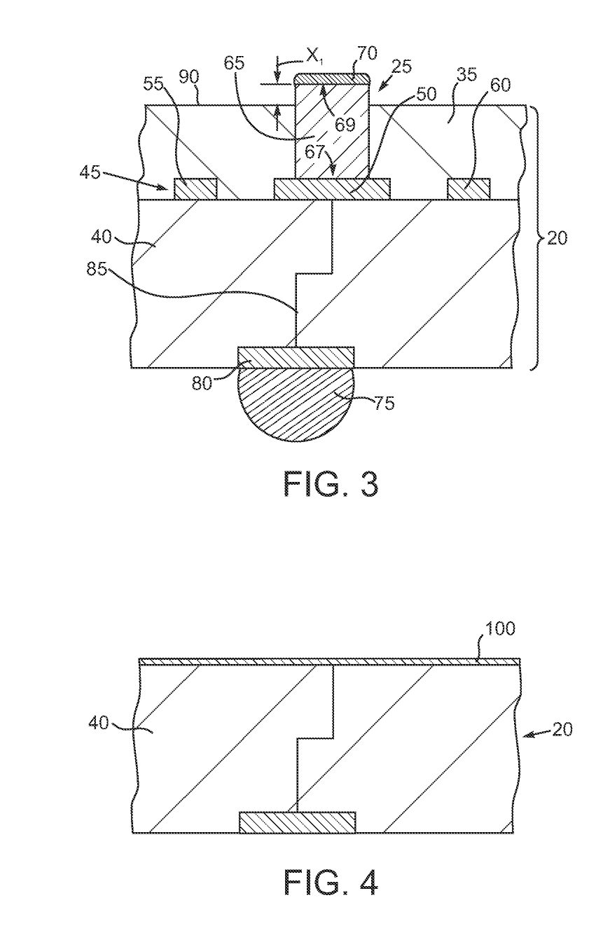

Attention is now turned to FIG. 3, which is a sectional view of FIG. 2 taken at section 3-3. The circuit board 20 may include a solder mask 35 applied to a substrate 40. The solder mask 35 may be composed of a variety of materials suitable for solder mask fabrication, such as, for example, PSR-4000 AUS703 manufactured by Taiyo Ink Mfg. Co., Ltd. or SR7000 manufactured by Hitachi Chemical Co., Ltd. Optionally, other materials, such as various epoxies or polymers such as polyimide may be used for the solder mask 35. When applied, the solder mask 35 covers an interconnect layer 45 that may include a conductor pad 50 and conductor traces 55 and 60. Note that because FIG. 3 depicts only a small portion of the circuit board 20 there may be many more of such conductor pads 50 and traces 55 and 60. The conductor structure 25 may consist of a conductor post 65 with an end 67 connected to the conductor pad 50 and an opposite end 69 that projects out of the solder mask 35. A conductor cap 70 may be coupled to the end 69 of the conductor post 65. The conductor post 65 may be composed of a variety of conducting materials such as copper, aluminum, silver, gold, platinum, titanium, refractory metals, refractory metal compounds, alloys of these or the like. In lieu of a unitary structure, the conductor post 65 may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the conductors. Various well-known techniques for applying metallic materials may be used, such as plating, physical vapor deposition, chemical vapor deposition, or the like. The conductor cap 70 may be composed of a variety of conductive materials such as various solders, tin, gold, silver combinations of these or the like. Lead-based or lead-free solders may be used.

As noted above, the substrate 40 may consist of a plurality of build up layers with or without a central core or be of monolithic construction. To interface with another circuit board or electronic device, the circuit board 20 may be provided with an interconnect scheme that in this illustrative embodiment consists of a ball grid array which includes a plurality of solder balls, one of which is shown and labeled 75. The solder ball 75 is connected to a conductor pad 80 of the substrate 40. The electrical pathway between the conductor pad 80 and the conductor pad 50 is represented schematically by the line 85. The skilled artisan will appreciate that the line 85 may actually consist of plural conductive layers interconnected by vias or other structures or by way of some other electrically conducting pathway. The electrical pathway 85 may be constructed from the same materials described elsewhere herein for the conductor post 65.

The conductor post 65, and in particular the end 69 thereof, projects away from an outer surface 90 of the solder mask 35 by some distance X₁. This spatial offset X₁ is advantageous to enable the ready coupling of the conductor structure 25 to one of the conductor structures used to connect to the semiconductor chip 15 such as the conductor structures 30 depicted in FIG. 1 and to provide a desired spatial separation between the semiconductor chip 15 and the circuit board 20.

An exemplary method for fabricating the conductor structure 25 may be understood by referring now to FIGS. 4, 5, 6, 7, 8, 9, 10 and 11 and initially to FIG. 4. FIG. 4 is a sectional view like FIG. 3 but of the circuit board 20 following the formation of the conductor pad 80 and the electrical pathway 85. Initially, a relatively thin conductive seed layer 100 may be applied to the substrate 40 of the circuit board 20. An appropriate thickness of the seed layer 100 will depend on the limitations of available manufacturing processes. In an exemplary embodiment the layer 100 may be about 0.5 to 1.5 μm thick. The seed layer 100 will be used as an electrode for a subsequent plating process. A variety of processes may be used to apply the layer 100, such as electroless plating, physical vapor deposition, chemical vapor deposition or the like. In an exemplary embodiment, an electroless copper plating may be used to establish a relatively thin seed layer 100.

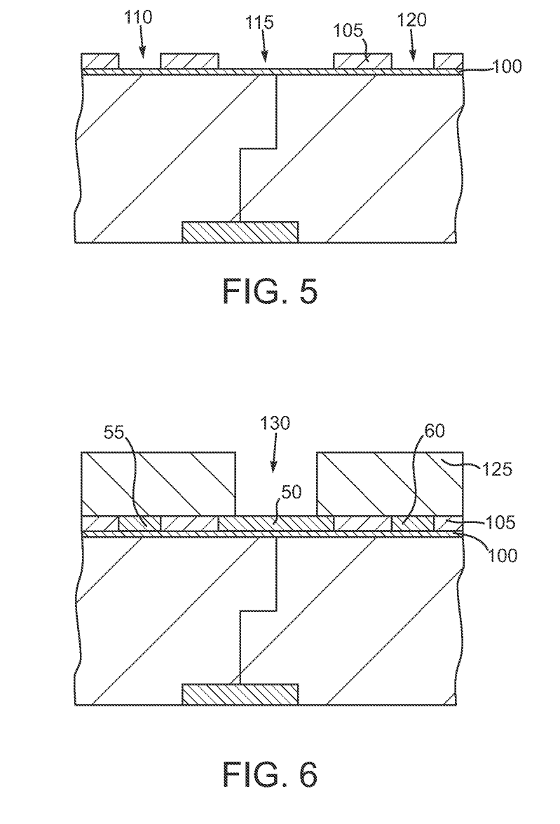

Referring now to FIG. 5, a photoresist mask 105 may be applied and lithographically patterned on the seed layer 100. The mask 105 has the openings 110, 115 and 120 suitably patterned with the desired shapes and locations for the later-formed conductor pads 50, 55 and 60 (depicted in FIG. 3). As shown in FIG. 6, a deposition process may be used to establish the conductor pads 50, 55 and 60. Here, a bulk plating process may be used with electrical bias using the seed layer 100 as a biased electrode. A variety of materials may be used for the conductor pads 50, 55 and 60 such as, for example, copper, aluminum, silver, gold, platinum, titanium, refractory metals, refractory metal compounds, alloys of these or the like. In lieu of a unitary structure, the conductor post 65 may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the conductors. An appropriate thickness of the conductor pads 50, 55 and 60 will depend on the limitations of available manufacturing processes. In an exemplary embodiment, the pads 50, 55 and 60 may be about 15 to 25 μm thick. Following the deposition process to establish the conductor pads 50, 55 and 60, the mask 105 is left in place and a second photolithography mask 125 may be applied over the first lithography mask 105 and the pads 50, 55 and 60. The photomask 125 may be lithographically patterned with an opening 130 that is positioned over the conductor pad 50 and suitably sized to have the desired foot print of the conductor post 65 depicted in FIG. 3. The lithographic patterning to establish the opening 130 may include not only an exposure and development process but also a resist trim if necessary.

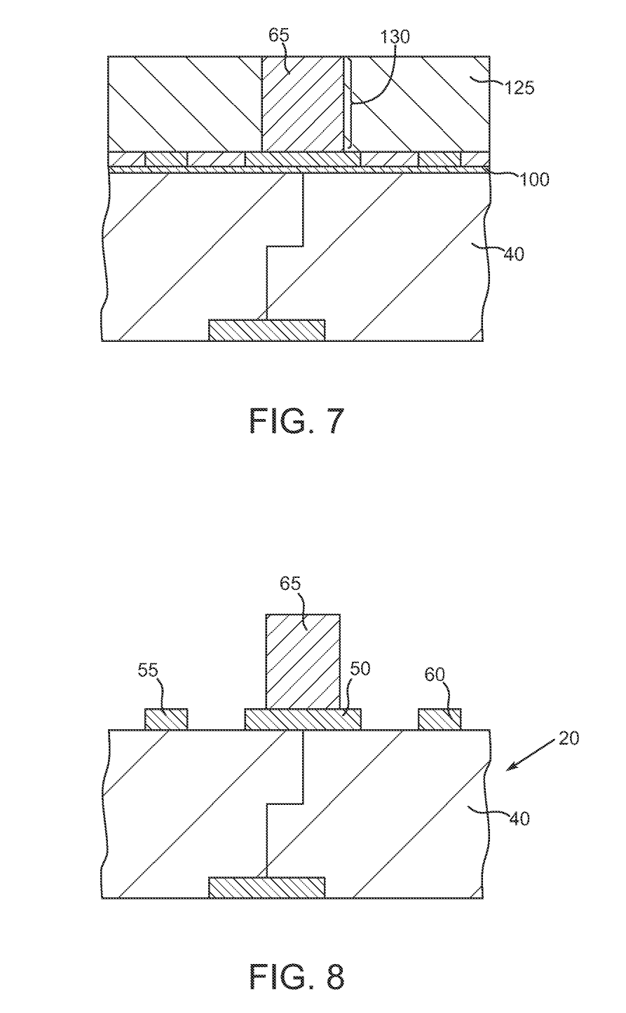

Referring now to FIG. 7, a material deposition process may be used to establish the conductor post 65 in the opening 130 of the photo mask 125. In an exemplary embodiment, an electrically biased plating process may be used to form the conductor pillar 65, again using the seed layer 100 as a conductive electrode. In this exemplary embodiment, copper is used for the conductor post 65. An appropriate thickness of the conductor post 65 will depend on the limitations of available manufacturing processes. In an exemplary embodiment, the conductor post 65 may be about 15 to 100 μm thick.

Referring now also to FIG. 8, the photomask 125 depicted in FIG. 7 may be stripped from the substrate 40 of the circuit board 20 using ashing, solvent stripping, or combinations of the two, in order to expose the conductor post 65 and the pads 50, 55 and 60. At this point, a flash etch may be performed to remove portions of the seed layer 100 shown in FIG. 7 lateral to the conductor pads 50, 55 and 60. The flash etch may consist of a wet etch. The portions of the seed layer 100 positioned beneath the conductor pads 50, 55 and 60 remain and may be deemed essentially merged with the conductor pads 50, 55 and 60 pictorially and thus those portions are not separately shown in FIG. 8 or subsequent figures.

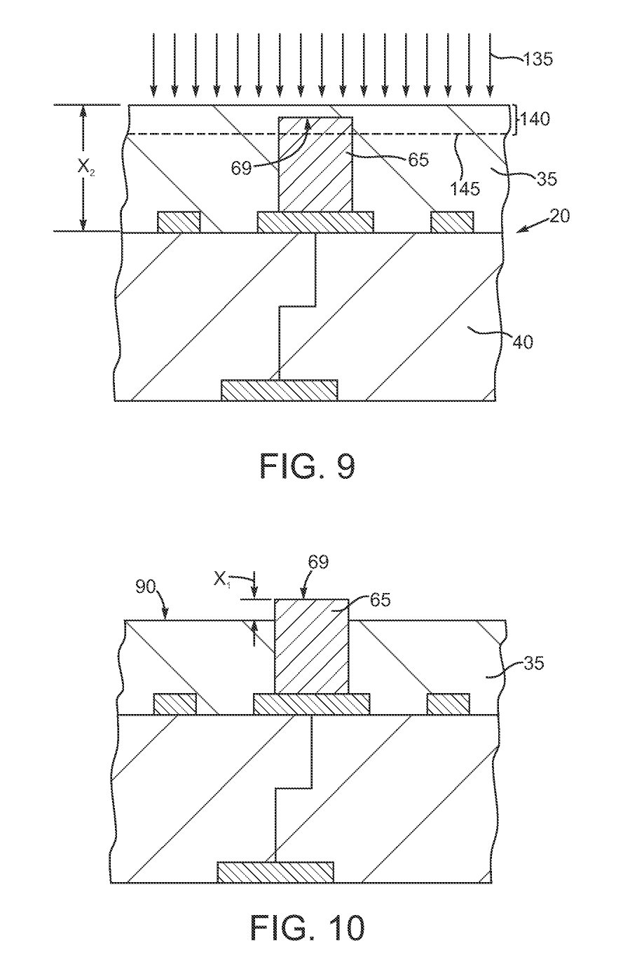

As shown in FIG. 9, the solder mask 35 may be applied to the substrate 40 of the circuit board 20 to some depth X₂ that covers the conductor post 65. It is desirable to process the solder mask 35 in such a way that a portion 140 thereof down to the level represented by the dashed line 140 may be removed to uncover the end 69 but leave the remainder of the conductor post 65 surrounded. This may be accomplished in a number of ways. In one alternative, the solder mask 35 may be flood exposed with radiation 135 of UV or other wavelength to change the solubility of the entire thickness of the solder mask 35. Thereafter, the solder mask 35 may be developed with a suitable developer for just long enough to dissolve the portion 140. Since the solder mask 35 may be composed of negative tone photoactive compounds, a subsequent developing process will remove the upper portion 140 of the solder mask 35 to expose an upper portion of the conductor post 65 as shown in FIG. 10. In another alternative, the parameters of the exposure radiation, such as duration, wavelength and energy, may be selected so that only the portion 140 of the solder mask 35 changes solubility. It is the position of the lower border 145 that will at least partially and possibly completely determine the desired vertical offset X₁ between the upper surface 90 of the solder mask 35 and the top of the conductor cap depicted in FIG. 3. At this point, the upper surface 90 of the solder mask 35 is offset from the end 69 of the conductor post 65 by the desired distance X₁. If the desired offset X₁ is not achieved by way of the first lithography process performed on the solder mask 35, then a subsequent blanket exposure and developing process or a resist trim of some sort could be used as desired.

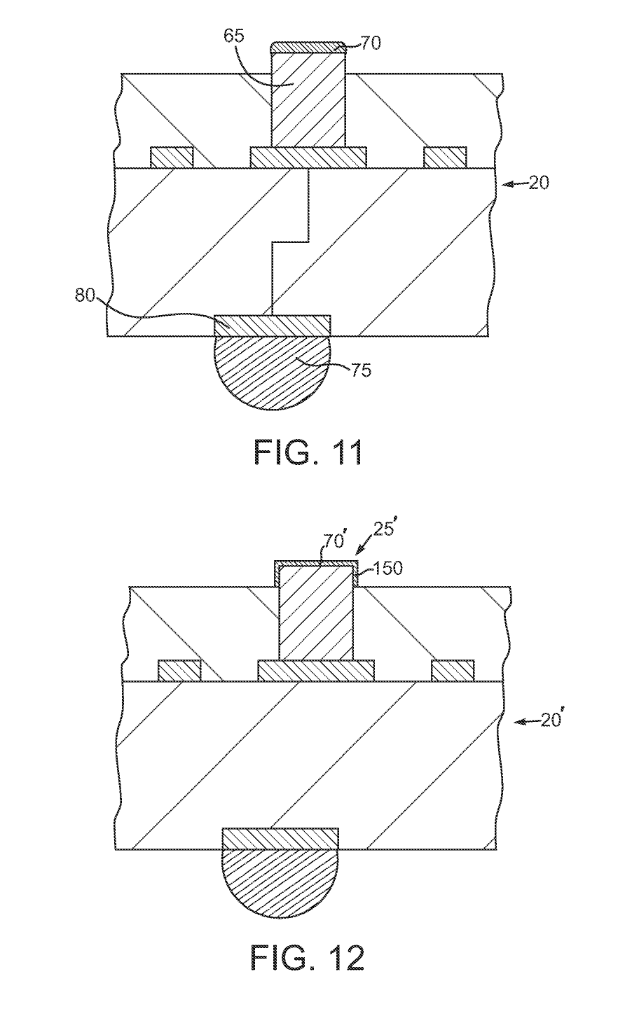

As shown in FIG. 11, the conductor cap 70 may be applied to the conductor post 65. In this illustrative embodiment, the conductor cap 70 may be composed of solder paste which may be applied to the conductor post 65 by way of printing, pick-and-place or other solder deposition techniques. If desired, the solder ball 75 may be applied to the conductor pad 80 at this stage and a reflow process established to firm up the metallurgical bond between not only the solder ball 75 and the pad 80 but also the conductor cap 70 and the conductor post 65 as well. The circuit board 20 may be next jointed to the semiconductor chip 15 by way of solder reflow, thermal bonding or other techniques appropriate for the interconnect structures 30 depicted in FIG. 1.

As noted above, the conductor cap 70 may be composed of various materials. In this regard, FIG. 12 depicts a sectional view like FIG. 11 but of an alternate exemplary circuit board 20′ with an alternate exemplary conductive cap 70′ that may consist of a plated metallic material or combinations of materials, such as tin, tin and silver or other materials. It is desirable for the sidewall 150 of the conductor cap 70′ to be relatively thin so that the spacing between the conductor structure 25′ and an adjacent conductor structure is not impacted.

It should be understood that the processes described herein that are performed on the exemplary circuit boards 20 and 20′ may be performed on a discrete circuit board or en masse on several circuit boards in strip or other forms. Protective masks (not shown) may be used to protect, for example, the conductor pad 80 (FIG. 3) and like structures during the processing.

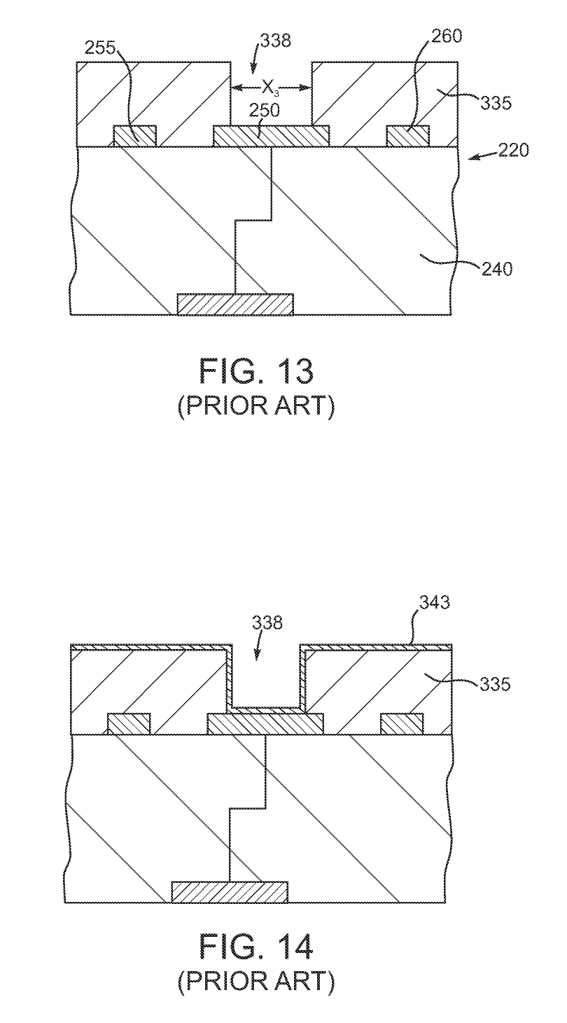

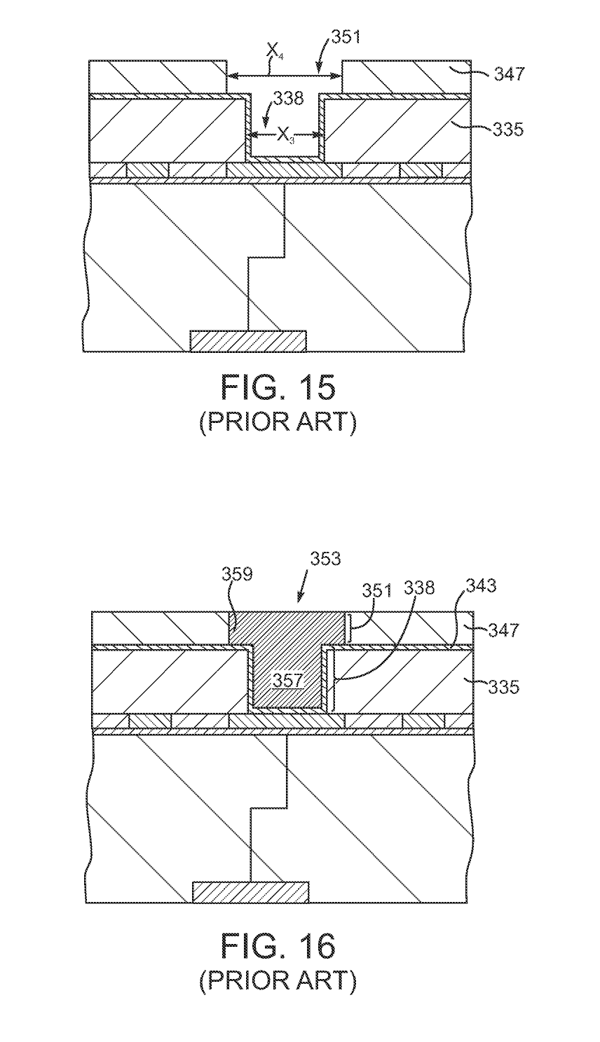

It may be useful at this point to contrast the disclosed exemplary embodiments with a conventional circuit board interconnect structure and a method for making the same. In this regard, attention is now turned to FIGS. 13-19 and initially to FIG. 13. FIG. 13 is a sectional view like FIG. 6 but of a conventional circuit board 220 that includes a substrate 240 upon which conductor pads 250, 255 and 260 are formed using the same general electroless seed layer plating, lithography and bulk plating process described above in conjunction with the formation of the conductor pads 50, 55 and 60 depicted in FIGS. 4, 5 and 6. Here, however, in lieu of a photolithography mask, a solder mask 335 is applied over the pads 250, 255 and 260 and patterned lithographically with an opening 338 that has a lateral dimension X₃. Next and as depicted in FIG. 14, an electroless plating process is used to deposit a conductive seed layer 343 over the solder mask 335 and particularly in the opening 338. Next and as depicted in FIG. 15, a photoresist mask 347 is formed on the conductive seed layer 343 with an opening 351 that is preferably concentric with the opening 338 in the solder mask 335. Due to the uncertainties in lithographic processing, the opening 351 must be formed with a lateral dimension X₄ which is much larger than the lateral dimension X₃ of the opening 338. The combination of the openings 338 and 351, and in particular the larger opening 351 with lateral dimension X₄, produces the somewhat mushroom-shaped appearance as shown in FIG. 15. This mushroom-shaped profile will have some important ramifications as illustrated and described further below. Referring now to FIG. 16, a bulk plating process is used to establish a conductor structure 353 in the combined openings 338 and 351 in the solder mask 335 and the photolithography mask 347, respectively. Here the conductive seed layer 343 acts as an electrode for the plating process to establish the conductor 353. Because of the aforementioned mushroom-shaped profile of the openings 338 and 351, the conductor structure 353 forms with cylindrical base 357 and a top flange 359, that when viewed from above, appears as a circle.

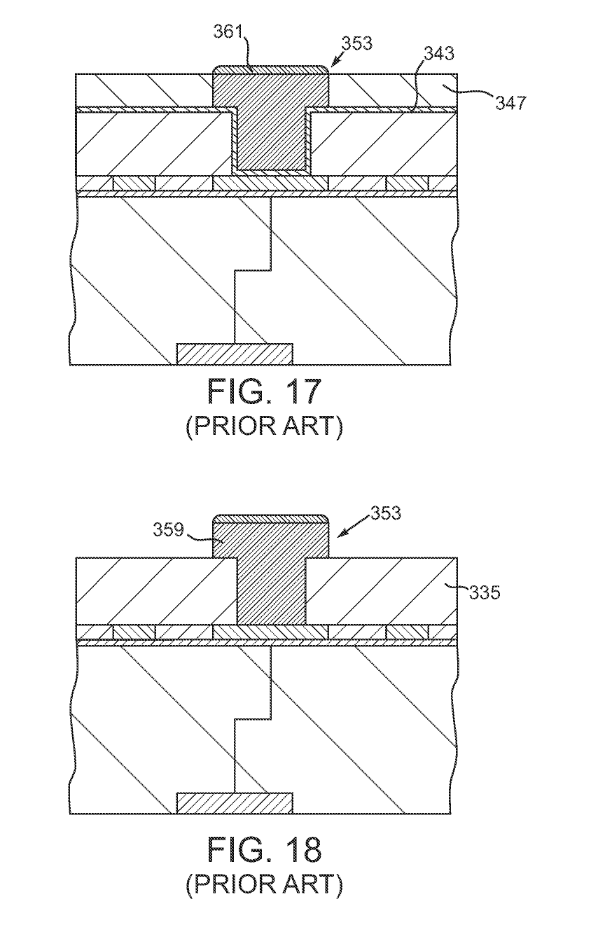

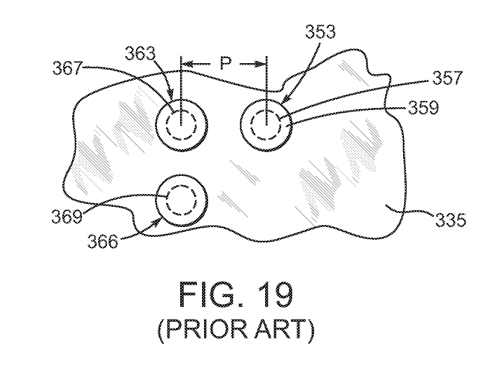

As shown in FIG. 17, a conductive cap 361 is applied to the conductor structure 353 while the photoresist mask 347 is in place. This step entails applying tin to the conductor structure 353 by electroplating or immersion. Finally, and as shown in FIG. 18, the lithography mask 347 is stripped to expose the flange 359 of the conductor structure 353 and flash etch processes performed to remove exposed portions of the conductive seed layer 343. Since the flange 359 effectively fans out across the solder mask 335, permissible packing density for the conductor structure 353 and similar conductor structures is limited. In this regard, attention is now turned to FIG. 19, which is a plan view of a small portion of the solder mask 335. The conductor structure 353 is visible along with two other similar conductor structures 363 and 366. The base portion 357 of the conductor structure 353 is shown in dashed. Note how the flange portion 359 projects laterally beyond the base portion 357. The base portions 367 and 369 of the conductor structures 363 and 366 are shown in phantom as well. Because of the flange 359 of the conductor structure 353 and the corresponding flanges of the conductor structures 363 and 366, the minimum pitch P between adjacent conductor structures such as 353 and 363 is limited beyond that which might be provided if there were no flange portions 359, etc.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a conductor post on a side of a circuit board, the conductor post including an end projecting away from the side of the circuit board;
applying a solder mask to the side of the circuit board to cover the conductor post; and
reducing a thickness of the solder mask so that a portion of the conductor post projects beyond the solder mask.

2. The method of claim 1, wherein the forming the conductor post comprises applying a mask to the side of the circuit board, patterning the mask with an opening and filling the opening with a conductor material.

3. The method of claim 2, wherein filling comprises plating.

4. The method of claim 1, comprising coupling a conductor cap to the portion of the conductor post.

5. The method of claim 1, wherein the reducing the thickness of the solder mask comprises exposing the solder mask with radiation having parameters preselected to render a portion of the solder mask proximate the end of the conductor post soluble in a developer, and dissolving the portion in the developer.

6. The method of claim 1, comprising forming the conductor post on a conductor pad.

7. The method of claim 1, comprising coupling a semiconductor chip to the conductor post.

8. The method of claim 1, wherein the circuit board comprises a semiconductor chip package substrate.

9. The method claim 1, wherein the conductor post is formed using instructions stored in a computer readable medium.

10. A method of manufacturing, comprising:
forming plural conductor posts on a side of a semiconductor chip package substrate, each of the conductor posts including an end projecting away from the side of the circuit board;
applying a solder mask to the side of the semiconductor chip package substrate to cover the plural conductor posts; and
reducing a thickness of the solder mask so that a portion of each of the conductor posts projects beyond the solder mask.

11. The method of claim 10, wherein the forming the plural conductor posts comprises applying a mask to the side of the circuit board, patterning the mask with plural openings opening and filling the plural openings with a conductor material.

12. The method of claim 11, wherein filling comprises plating.

13. The method of claim 10, comprising coupling a conductor cap to the portions of each of the conductor posts.

14. The method of claim 10, wherein the reducing the thickness of the solder mask comprises exposing the solder mask with radiation having parameters preselected to render a portion of the solder mask proximate the ends of the conductor posts soluble in a developer, and dissolving the portion of the solder mask in the developer.

15. The method of claim 10, comprising coupling a semiconductor chip to the plural conductor posts.

16. An apparatus, comprising:
a circuit board including a side;
a solder mask coupled to the side of the circuit board; and
a conductor post coupled to the side of the circuit board and including a first end projecting into the solder mask and a second end projecting out of the solder mask, wherein the second end is not wider than the first end.

17. The apparatus of claim 16, comprising plural conductor posts coupled to the side of the circuit board, each of the conductor posts including a first end projecting into the solder mask and a second end projecting out of the solder mask, wherein the second end is not wider than the first end.

18. The apparatus of claim 16, comprising a conductor cap coupled to the second end of the conductor post.

19. The apparatus of claim 16, comprising a semiconductor chip coupled to the conductor post.

20. The apparatus of claim 16, wherein the circuit board comprises a semiconductor chip package substrate.
